(19) United States
(12) Patent Application Publication
(10) Pub. No.: US 2024/0128221 A1
(43) Pub. Date: Apr. 18, 2024

(54) SEMICONDUCTOR PACKAGE INCLUDING BUMPS WITH A PLURALITY OF SEPARATION DISTANCES

(71) Applicant: SAMSUNG ELECTRONICS CO., LTD., Suwon-si (KR)

(72) Inventors: Minsoo Kim, Suwon-si (KR); Seongyo Kim, Suwon-si (KR); Sangsick Park, Suwon-si (KR); Soyoun Lee, Suwon-si (KR)

(73) Assignee: SAMSUNG ELECTRONICS CO., LTD., Suwon-si (KR)

(21) Appl. No.: 18/367,642

(22) Filed: Sep. 13, 2023

(30) Foreign Application Priority Data
Oct. 13, 2022 (KR) 10-2022-0131657

(51) Int. Cl. H01L 23/00; H01L 25/065

(52) U.S. Cl. CPC H01L 24/16; H01L 24/29; H01L 24/32; H01L 24/73; H01L 25/0657; H01L 24/27; H01L 2224/16148; H01L 2224/278; H01L 2224/29018; H01L 2224/29552; H01L 2224/32145; H01L 2224/73204; H01L 2225/06513; H01L 2225/06541; H01L 2924/381

(57) ABSTRACT

According to embodiments of the present disclosure, a semiconductor package is provided. The semiconductor package includes a substrate including a first surface and a second surface opposite to the first surface; and a plurality of lower pads on the second surface at different intervals. The semiconductor package further includes: a plurality of bumps attached to the plurality of lower pads; a first non-conductive film on the second surface of the substrate; and a second non-conductive film on the first non-conductive film. A plurality of regions are defined in the semiconductor package according to a separation distance between the plurality of bumps, such that each region of the plurality of regions includes respective bumps, from among the plurality of bumps, that have a respective separation distance between neighboring ones of the respective bumps within the region. A sum of thicknesses of the first and second non-conductive films is constant.

### CROSS-REFERENCE TO RELATED APPLICATION

This application is based on and claims priority under 35 U.S.C. § 119 to Korean Patent Application No. 10-2022-0131657, filed on Oct. 13, 2022, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package including a non-conductive film.

### 2. Description of Related Art

Recently, the demand for a portable device has been rapidly increasing in the electronic product market, and thus, miniaturization and weight reduction of electronic components mounted on these products, for example, semiconductor chips, are continuously required. In order to realize miniaturization and weight reduction of electronic components, semiconductor package technology in which a plurality of semiconductor chips constituting a component are integrated into one package is required.

### SUMMARY

According to embodiments of the present disclosure, a semiconductor package for suppressing a fillet phenomenon of a non-conductive film is provided.

According to embodiments of the present disclosure, a semiconductor package for improving coverage quality of a non-conductive film is provided.

Problems solved by embodiments of the present disclosure are not limited to the above problems, and other problems that are solved by embodiments of the present disclosure may be clearly understood by a person skilled in the art from the following description.

According to embodiments of the present disclosure, a semiconductor package is provided. The semiconductor package includes a semiconductor chip including a substrate including a first surface and a second surface opposite to the first surface; and a plurality of lower pads on the second surface at different intervals. The semiconductor package further includes: a plurality of bumps attached to the plurality of lower pads; a first non-conductive film on the second surface of the substrate; and a second non-conductive film on the first non-conductive film. A plurality of regions are defined in the semiconductor package according to a separation distance between the plurality of bumps, such that each region of the plurality of regions includes respective bumps, from among the plurality of bumps, that have a respective separation distance between neighboring ones of the respective bumps within the region. A sum of thicknesses of the first non-conductive film and the second non-conductive film is constant. An elastic modulus of the first non-conductive film and an elastic modulus of the second non-conductive film are different from each other.

According to embodiments of the present disclosure, a semiconductor package is provided. The semiconductor package includes a first semiconductor chip including: a first substrate including a first surface and a second surface opposite to the first surface; a plurality of power vias penetrating at least a portion of the first substrate between the first surface and the second surface of the first substrate; and a plurality of first upper pads on the first surface of the first substrate at different intervals. The semiconductor package further includes a second semiconductor chip including: a second substrate including a third surface and a fourth surface opposite to the third surface; and a plurality of second lower pads, corresponding to the plurality of first upper pads, on the fourth surface of the second substrate. The semiconductor package further includes a plurality of bumps between the first semiconductor chip and the second semiconductor chip and connecting the plurality of first upper pads to the plurality of second lower pads; a first non-conductive film on the fourth surface of the second semiconductor chip; and a second non-conductive film between the first non-conductive film and the first semiconductor chip. A plurality of regions are defined in the semiconductor package according to a separation distance between the plurality of bumps, such that each region of the plurality of regions includes respective bumps, from among the plurality of bumps, that have a respective separation distance between neighboring ones of the respective bumps within the region. An elastic modulus of the first non-conductive film and an elastic modulus of the second non-conductive film are different from each other.

According to embodiments of the present disclosure, a semiconductor package is provided. The semiconductor package includes a semiconductor chip including: a substrate including a first surface and a second surface opposite to the first surface; and a plurality of lower pads on the second surface. The semiconductor package further includes: a plurality of bumps attached to the plurality of lower pads; a first non-conductive film on the second surface; and a second non-conductive film on the first non-conductive film. An elastic modulus of the second non-conductive film is greater than an elastic modulus of the first non-conductive film. A plurality of regions are defined in the semiconductor package according to a separation distance between the plurality of bumps, such that each region of the plurality of regions includes respective bumps, from among the plurality of bumps, that have a respective separation distance between neighboring ones of the respective bumps within the region. The plurality of regions includes: a first region that includes at least a part of each of four sides of the second surface of the semiconductor chip; a second region that includes four vertices of the second surface of the semiconductor chip; and a third region that includes a central region of the second surface of the semiconductor chip. A sum of thicknesses of the first non-conductive film and the second non-conductive film is the same as a sum of thicknesses of the plurality of bumps and the plurality of lower pads. The separation distance between the neighboring ones of the respective bumps of the first region is greater than the separation distance between the neighboring ones of the respective bumps of the second region and the separation distance between the neighboring ones of the respective bumps of the third region. A thickness of a portion of the first non-conductive film in the first region is less than thicknesses of portions of the first non-conductive film in the second region and the third region.

### BRIEF DESCRIPTION OF DRAWINGS

Embodiments of the present disclosure will be more clearly understood from the following detailed description taken in conjunction with the accompanying drawings in which:

FIG. 1 is a plan view schematically illustrating a semiconductor package according to an embodiment of the present disclosure;

FIG. 2 is a cross-sectional view illustrating the semiconductor package of FIG. 1, which is taken along a line X-X′ of FIG. 1;

FIG. 3 is a cross-sectional view illustrating the semiconductor package of FIG. 1, which is taken along a line Y-Y′ of FIG. 1;

FIG. 4 is a plan view schematically illustrating a semiconductor package according to an embodiment of the present disclosure;

FIG. 5 is a cross-sectional view illustrating the semiconductor package of FIG. 4, which is taken along a line Z-Z′ of FIG. 4;

FIG. 6 is a plan view schematically illustrating a semiconductor package according to an embodiment of the present disclosure;

FIG. 7 is a cross-sectional view illustrating the semiconductor package of FIG. 6, which is taken along a line X1-X1′ of FIG. 6;

FIG. 8 is a cross-sectional view illustrating the semiconductor package of FIG. 6, which is taken along a line Y1-Y1′ of FIG. 6;

FIG. 9 is a plan view schematically illustrating a semiconductor package according to an embodiment of the present disclosure;

FIG. 10 is a cross-sectional view illustrating a semiconductor package of FIG. 9, which is taken along a line Z1-Z1′ of FIG. 9; and

FIG. 11A is a first cross-sectional view illustrating a method of manufacturing a semiconductor package, according to an embodiment of the present disclosure;

FIG. 11B is a second cross-sectional view illustrating the method of manufacturing the semiconductor package, according to the embodiment of the present disclosure;

FIG. 11C is a third cross-sectional view illustrating the method of manufacturing the semiconductor package, according to the embodiment of the present disclosure.

### DETAILED DESCRIPTION

Since embodiments of the present disclosure may apply various changes and have various forms, some example embodiments will be illustrated in the drawings and described in detail. However, the example embodiments do not limit the embodiments of the present disclosure to specific forms described.

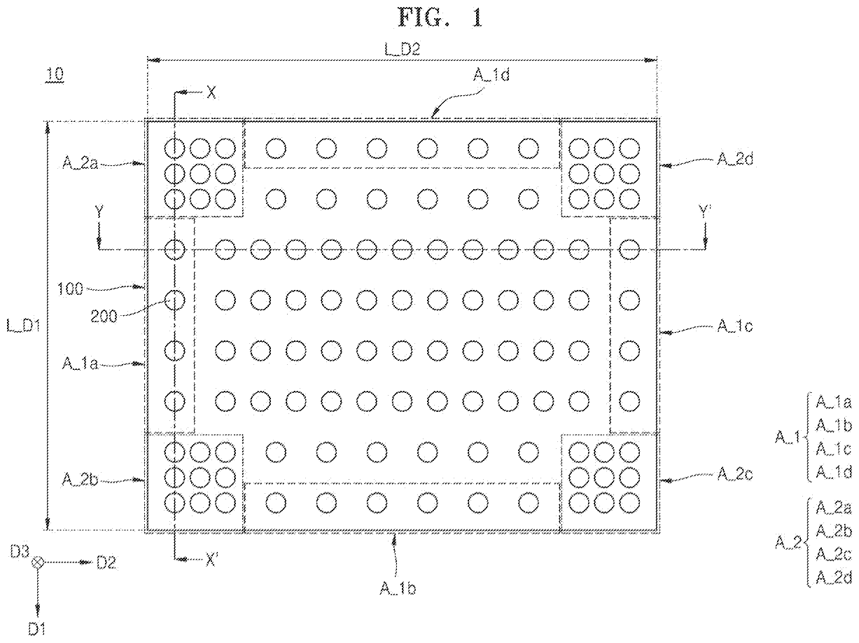

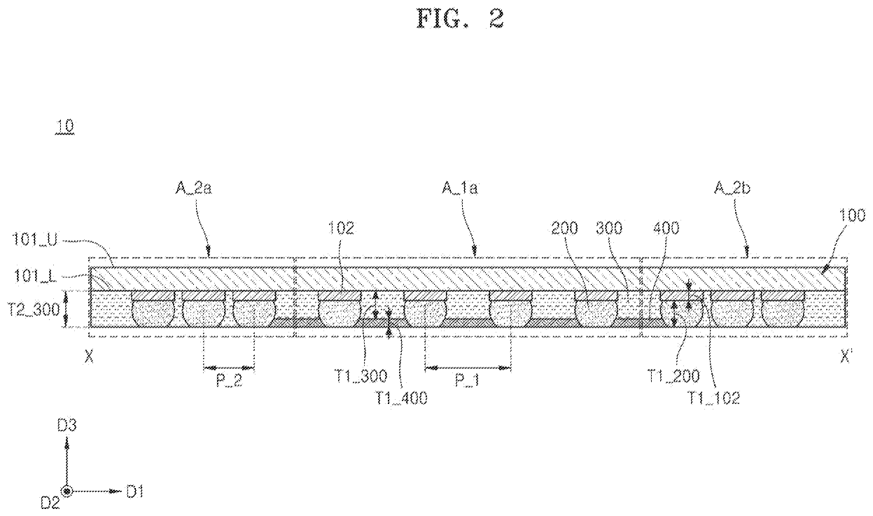

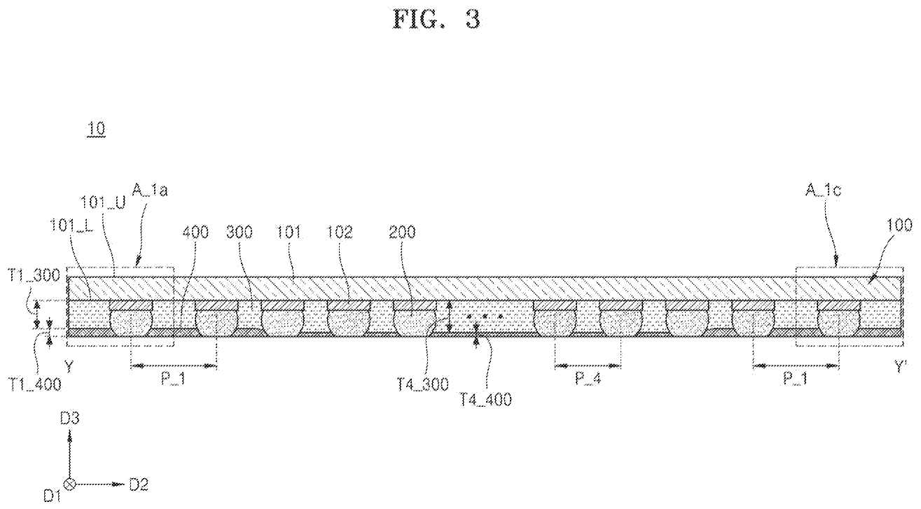

FIG. 1 is a plan view schematically illustrating a semiconductor package according to an embodiment of the present disclosure. FIG. 2 is a cross-sectional view illustrating the semiconductor package of FIG. 1, which is taken along a line X-X′ line in FIG. 1. FIG. 3 is a cross-sectional view illustrating the semiconductor package of FIG. 1, which is taken along a line Y-Y′ of FIG. 1.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Referring to FIGS. 1 to 3, a semiconductor package 10 may include a semiconductor chip 100, a plurality of bumps 200, a first non-conductive film 300, and a second non-conductive film 400.

The semiconductor chip 100 of the semiconductor package 10 may include a substrate 101 and lower pads 102.

The substrate 101 may have a first surface 101_U and a second surface 101_L. For example, the first surface 101_U of the substrate 101 may be one surface of the substrate 101 on which an upper pad is arranged, and the second surface 101_L of the substrate 101 may be one surface of the substrate 101 on which the lower pads 102 are arranged.

Hereinafter, horizontal directions D1 and D2 may be defined as directions parallel to directions in which the first surface 101_U and the second surface 101_L of the substrate 101 extend, and a vertical direction D3 may be defined as a direction perpendicular to the directions in which the first surface 101_U and the second surface 101_L extend.

In some embodiments, the constituent material of the substrate 101 of the semiconductor chip 100 may include silicon (Si). In addition, the material of the substrate 101 may include semiconductor elements, such as germanium (Ge), or compound semiconductors, such as silicon carbide (SiC), gallium arsenide (GaAs), indium arsenide (InAs), and indium phosphate (InP). However, the constituent materials of the substrate 101 are not limited to those described above.

In an embodiment, the substrate 101 may include an active layer. The active layer may include various types of individual devices. The plurality of individual devices may include various microelectronic devices, for example, a complementary metal-oxide semiconductor (CMOS) transistor, a metal-oxide-semiconductor transistor (MOSFET), and the like.

The lower pads 102 of the semiconductor chip 100 may be arranged on the second surface 101_L of the substrate 101 and electrically connected to the plurality of individual devices in the active layer of the substrate 101. The lower pads 102 may be electrically connected to each other by a metal wiring structure provided in the substrate 101. The second surface 101_L of the substrate 101 may be an active surface.

In an embodiment, the thickness of each of the lower pads 102 in the vertical direction D3 may be in a range of about 10 micrometers to about 100 micrometers. However, the thickness of each of the lower pads 102 in the vertical direction D3 is not limited to the values described above.

In an embodiment, the semiconductor chip 100 may further include a passivation layer (not shown) of an insulating material arranged on the second surface 101_L of the substrate 101 and surrounding the sides of the lower pads 102. The lower surface of each of the lower pads 102 may be exposed from the passivation layer.

In an embodiment, the constituent material of the lower pads 102 may include copper (Cu). However, embodiments are not limited thereto, and the constituent materials of the lower pads 102 may include a metal, such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), etc., or an alloy thereof.

In an embodiment, the semiconductor chip 100 may include a memory semiconductor chip. For example, a memory semiconductor chip may include a volatile memory semiconductor chip, such as Dynamic Random Access Memory (DRAM) or Static Random Access Memory (SRAM), and a non-volatile memory semiconductor chip, such as Phase-Change Random Access Memory (PRAM), Magneto-Resistive Random Access Memory (MRAM), a Ferroelectric Random Access Memory (FeRAM), or Resistive Random Access Memory (RRAM).

However, the embodiments of the present disclosure are not limited thereto, and the semiconductor chip 100 may include a logic semiconductor chip. For example, the logic semiconductor chip may include a logic semiconductor chip, such as a Central Processor Unit (CPU), a Microprocessor Unit (MPU), a Graphic Processor Unit (GPU), or an Application Processor (AP). In addition, the semiconductor chip 100 may include a buffer chip.

The plurality of bumps 200 of the semiconductor package 10 may be attached to the lower pads 102 of the semiconductor chip 100, respectively. The plurality of bumps 200 may be attached to a plurality of corresponding lower pads 102, respectively. The plurality of bumps 200 may be configured to electrically and physically connect the semiconductor chip 100 with an external device on which the semiconductor chip 100 is mounted.

In some embodiments, the plurality of bumps 200 may include solder balls, respectively. In some embodiments, the material forming the plurality of bumps 200 may include at least one alloy selected from the group consisting of a Sn—Ag—Cu alloy, a Sn—Bi alloy, a Sn—Bi—Ag alloy, and a Sn—Ag—Cu—Ni alloy.

The first non-conductive film 300 of the semiconductor package 10 may be positioned on the second surface 101_L of the substrate 101. The second non-conductive film 400 of the semiconductor package 10 may be positioned on the first non-conductive film 300. In other words, the semiconductor chip 100, the first non-conductive film 300, and the second non-conductive film 400 may be sequentially stacked.

The sum of the thicknesses of the first non-conductive film 300 and the second non-conductive film 400 may be constant. In some embodiments, even if the thickness of each of the first non-conductive film 300 and the second non-conductive film 400 varies depending on a region, the sum of the thicknesses of the first non-conductive film 300 and the second non-conductive film 400 may be the same. In some embodiments, the sum of the thicknesses of the first non-conductive film 300 and the second non-conductive film 400 may range from about 7 μm to about 11 μm

The sum of the thickness of the first non-conductive film 300 and the thickness of the second non-conductive film 400 may be substantially the same as the sum of the thickness T1_102 of each of the lower pads 102 and the thickness T1_200 of each of the plurality of bumps 200. In some embodiments, after placing the first non-conductive film 300 and the second non-conductive film 400 on the plurality of bumps 200 attached on the lower pads 102, a planarization process may be performed. After the planarization process is performed, the lower surfaces of the plurality of bumps 200 may be exposed to the outside and may be planar. In other words, the first non-conductive film 300 and the second non-conductive film 400 may not be positioned on the upper and lower surfaces of each of the plurality of bumps 200. After the planarization process is performed, the first non-conductive film 300 and the second non-conductive film 400 may be positioned on the side surfaces of the plurality of bumps 200. In other words, the first non-conductive film 300 and the second non-conductive film 400 may fill spaces between the plurality of bumps 200. After the planarization process is performed, the sum of the thicknesses of the first non-conductive film 300 and the second non-conductive film 400 may be equal to the sum of the thickness T1_102 of each of the lower pads 102 and the thickness T1_200 of each of the plurality of bumps 200.

An elastic modulus of the first non-conductive film 300 may be different from an elastic modulus of the second non-conductive film 400. In some embodiments, the elastic modulus of the second non-conductive film 400 may be greater than the elastic modulus of the first non-conductive film 300. That is, when the same force is applied to the second non-conductive film 400 and the first non-conductive film 300, the strain rate of the second non-conductive film 400 may be less than that of the first non-conductive film 300.

The first non-conductive film 300 and the second non-conductive film 400 may each include an adhesive resin and flux. The adhesive resin may adhere the first non-conductive film 300 to the semiconductor chip 100. The adhesive resin may be, for example, a thermosetting resin. That is, when the adhesive resin is subjected to heat and pressure, the adhesive resin changes from a gel state to a liquid state and then is cured.

In some embodiments, the size of the adhesive resin of the second non-conductive film 400 may be greater than the size of the adhesive resin of the first non-conductive film 300. The content of the adhesive resin of the second non-conductive film 400 may be greater than the content of the adhesive resin of the first non-conductive film 300.

The flux may be used for soldering for electrical bonding of the semiconductor chip 100 in a semiconductor package manufacturing process. The flux may improve the spreadability and wettability of a solder. For example, fluxes are classified into resin-based, organic-based, and inorganic-based, and fluxes used in electronic devices are generally resin-based.

In a comparative embodiment, during the bonding process between semiconductor chips, a fillet phenomenon in which the non-conductive film overflows near the edge of the semiconductor chip may occur. The semiconductor package 10 of an embodiment of the present disclosure may suppress a fillet phenomenon by the second non-conductive film 400 being on at least a portion of the sides of the second surface of the semiconductor chip 100.

The semiconductor package 10 may include a plurality of regions having different separation distances between the plurality of bumps 200. That is, the separation distances between the plurality of bumps 200 may vary depending on the regions of the semiconductor package 10. As the separation distance between the plurality of bumps 200 may increase, the thickness of the first non-conductive film 300 may decrease. That is, the thickness of the first non-conductive film 300 may be adjusted by adjusting the separation distance between the plurality of bumps 200.

In an embodiment, the semiconductor package 10 may include a first region A_1 and a second region A_2.

In some embodiments, the first region A_1 may include at least a portion of each of four sides of the second surface 101_L of the semiconductor chip 100. In some embodiments, the first region A_1 may include a first-a region A_1a, a first-b region A_1b, a first-c region A_1c, and a first-d region A_1d, which include at least a portion of each side of the second surface 101_L. The second region A_2 may include four vertices of the second surface 101_L of the semiconductor chip 100. That is, the second region A_2 may include a second-a region A_2a, a second-b region A_2b, a second-c region A_2c, and a second-d region A_2d, which include each vertex of the second surface 101_L.

In some embodiments, the semiconductor chip 100 may have a first length L_D1 in the first direction D1 and a second length L_D2 in the second direction D2. The first-a region A_1a of the first region A_1 may have a length in the range of about 50% to about 80% of the first length L_D1 in the first direction D1, and may have a length in the range of about 400 μm to about 600 μm in the second direction D2. However, the lengths in the first direction D1 and the second direction D2 of the first-a region A_1a are not limited to the values described above. In some embodiments, each of the first-b region A_1b, the first-c region A_1c, and the first-d region A_1d may have the same area as the first-a region A_1a. In some embodiments, the first-a region A_1a and the first-c region A_1c may be symmetrical with respect to the center point of the second surface 101_L, and the first-b region A_1b and the first-d region A_1d may be symmetrical with respect to the center point of the second surface 101_L.

In some embodiments, the second-a region A_2a of the second region A_2 may have a length in a range of about 20% to about 50% of the first length L_D1 in the first direction D1, and have a length in a range of about 20% to about 50% of the second length L_D2 in the second direction D2. However, the lengths in the first direction D1 and the second direction D2 of the second-a region A_2a are not limited to the values described above. Each of the second-b region A_2b, the second-c region A_2c, and the second-d region A_2d may have the same area as the second-a region A_2a. The second-a region A_2a and the second-c region A_2c may be symmetrical with respect to the center point of the second surface 101_L, and the second-b region A_2b and the second-d region A_2d may be symmetrical with respect to the center point of the second surface 101_L.

In some embodiments, the first region A_1 may be located between the second regions A_2.

The separation distances between the plurality of bumps 200 may be different in the first area A_1 and the second area A_2. In some embodiments, the separation distance between the plurality of bumps 200 may be the first distance P_1 in the first region A_1 and the second distance P_2 in the second region A_2. In some embodiments, the second distance P_2 may be less than the first distance P_1. In some embodiments, the first distance P_1 may be in the range of about 60 μm to about 100 μm, and the second distance P_2 may be in the range of about 20 μm to about 40 μm.

In some embodiments, the separation distance between the plurality of bumps 200 located in regions not included in the first region A_1 and the second region A_2 may be a fourth distance P_4. The fourth distance P_4 may be less than the first distance P_1 and greater than the second distance P_2. In some embodiments, the first distance P_1 may be in the range of about 60 μm to about 100 μm, the second distance P_2 may be in the range of about 20 μm to about 30 μm, and the fourth distance P_4 may be in the range of about 35 μm to about 50 μm.

As the separation distance between the plurality of bumps 200 may decrease, the thickness of the first non-conductive film 300 may increase. The thickness of the first non-conductive film 300 in the first region A_1 may be less than the thickness of the first non-conductive film 300 in the second region A_2. In some embodiments, the thickness of the first non-conductive film 300 may be a first thickness T1_300 in the first region A_1, a second thickness T2_300 in the second region A_2, and a fourth thickness T4_300 in regions not included in the first region A_1 and the second region A_2. The first thickness T1_300 may be less than the second thickness T2_300, and the fourth thickness T4_300 may be greater than the first thickness T1_300 and less than the second thickness T2_300.

In some embodiments, the first thickness T1_300 may be in the range of about 5 μm to about 8 μm, the second thickness T2_300 may be in the range of about 9 μm to about 10 μm, and the fourth thickness T4_300 may be in the range of about 8 μm to about 9 μm.

In some embodiments, the sum of the thickness of the first non-conductive film 300 and the thickness of the second non-conductive film 400 may be equal to the sum of the thickness T1_102 of each of the lower pads 102 and the thickness T1_200 of each of the plurality of bumps 200. The first thickness T1_300 may range from about 60% to about 90% of the sum of the thickness of the first non-conductive film 300 and the thickness of the second non-conductive film 400. The second thickness T2_300 may range from about 90% to about 100% of the sum of the thickness of the first non-conductive film 300 and the thickness of the second non-conductive film 400.

In other words, the sum of the thickness of the first non-conductive film 300 and the thickness of the second non-conductive film 400 in the first region A_1 may be the same as the sum of the thickness of the first non-conductive film 300 and the thickness of the second non-conductive film 400 in the second region A_2. In the second region A_2 in which the thickness of the first non-conductive film 300 is great, the thickness of the second non-conductive film 400 may be less than thicknesses of the second non-conductive film 400 in the other regions. In the first region A_1 in which the thickness of the first non-conductive film 300 is small, the thickness of the second non-conductive film 400 may be greater than the thickness of the second non-conductive film 400 in the other regions.

Since the separation distance between the plurality of bumps 200 in the first region A_1 of the semiconductor package 10 is greater than the separation distances between the plurality of bumps 200 in other regions, the thickness of the first non-conductive film 300 may be formed small. When the thickness of the first non-conductive film 300 is small, the thickness of the second non-conductive film 400 may increase, and thus, the deformation rate of the non-conductive film in the first region A_1 may decrease. By adjusting the separation distance between the plurality of bumps 200, the overflow of the non-conductive film occurring on the side of the second surface 101_L of the semiconductor chip 100 may be suppressed, thereby suppressing the fillet phenomenon of the semiconductor package 10.

In addition, since the separation distance between the plurality of bumps 200 in the second region A_2 of the semiconductor package 10 is less than the separation distances between the plurality of bumps 200 in other regions, the thickness of the first non-conductive film 300 may be formed large. In some embodiments, since the second non-conductive film 400 is not present on the first non-conductive film 300 in the second region A_2, adhesion of the non-conductive film in the second region A_2 may be improved. It is possible to improve the quality of the semiconductor package 10 by improving coverage at the vertices of the semiconductor chip 100 by adjusting the separation distances between the plurality of bumps 200.

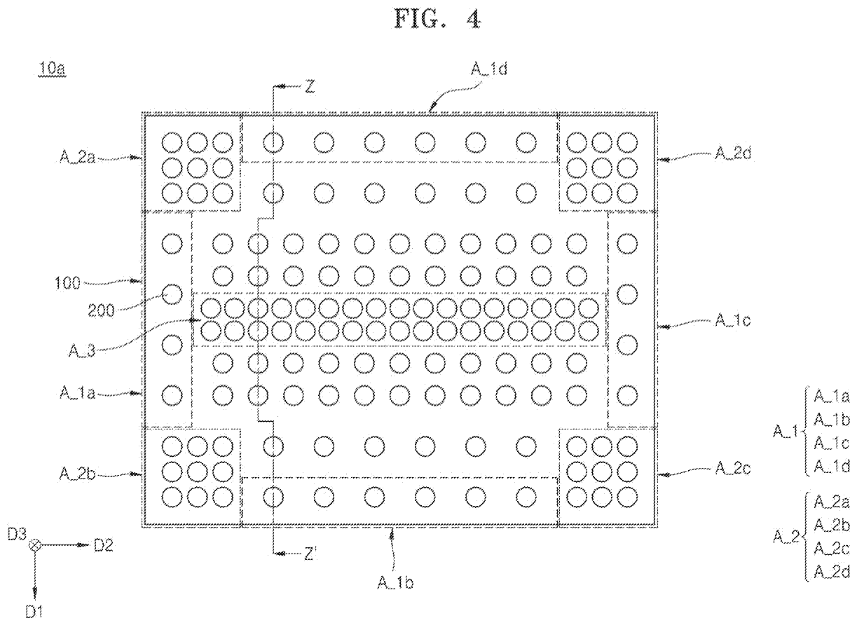

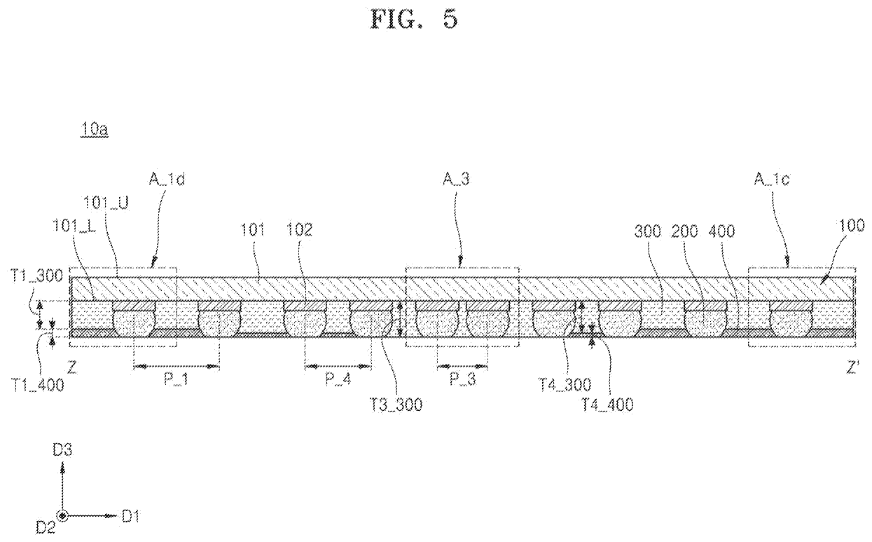

FIG. 4 is a plan view schematically illustrating a semiconductor package according to an embodiment. FIG. 5 is a cross-sectional view illustrating the semiconductor package of FIG. 4, which is taken along a line Z-Z′ line in FIG. 5.

Hereinafter, redundant description between the semiconductor package 10a of FIG. 4 and the semiconductor package 10 of FIG. 1 is omitted and a difference therebetween is described.

Referring to FIGS. 2, 4, and 5, the semiconductor package 10a may include a first region A_1, a second region A_2, and a third region A_3. In some embodiments, the semiconductor chip 100 may have a first length in the first direction D1 and a second length in the second direction D2.

In some embodiments, the first region A_1 may include at least a portion of four sides of the second surface 101_L of the semiconductor chip 100. In some embodiments, the first region A_1 may include a first-a region A_1a, a first-b region A_1b, a first-c region A_1c, and a first-d region A_1d, in each side of the second surface 101_L of the semiconductor chip 100. In some embodiments, the first-a region A_1a of the first region A_1 may have a length in the range of about 50% to about 80% of the first length in the first direction D1, and may have a length in the range of about 400 μm to about 600 μm in the second direction D2.

In some embodiments, the second region A_2 may include four vertices of the second surface 101_L of the semiconductor chip 100. That is, the second region A_2 may include a second-a region A_2a, a second-b region A_2b, a second-c region A_2c, and a second-d region A_2d, at each vertex of the second surface 101_L. In some embodiments, the second-a region A_2a of the second region A_2 may have a length in a range of about 20% to about 50% of the first length in the first direction D1, and have a length in a range of about 20% to about 50% of the second length in the second direction D2.

In some embodiments, the third region A_3 may include a central portion of the second surface 101_L of the semiconductor chip 100. In an embodiment, the third region A_3 may be located between the first-a region A_1a and the first-c region A_1c and between the first-b region A_1b and the first-d region A_1d. In some embodiments, the third region A_3 may have a length in a range of about 30% to about 50% of the first length in the first direction D1 and a length in a range of about 60% to about 80% of the second length in the second direction D2.

The separation distances between the plurality of bumps 200 may be different in the first region A_1, the second region A_2, and the third region A_3. In some embodiments, the separation distance between the plurality of bumps 200 may be the first distance P_1 in the first region A_1, the second distance P_2 in the second region A_2, and the third distance P_3 in the third region A_3.

In some embodiments, a separation distance between a plurality of bumps 200 located in regions not included in the first region A_1, the second region A_2, and the third region A_3 may be a fourth distance P_4. The fourth distance P_4 may be less than the first distance P_1 and greater than the second distance P_2.

In some embodiments, the second distance P_2 may be less than the first distance P_1. In some embodiments, the first distance P_1 may be in the range of about 60 μm to about 100 μm, and the second distance P_2 may be in the range of about 20 μm to about 40 μm.

In some embodiments, the third distance P_3 may be less than the first distance P_1. In some embodiments, the first distance P_1 may be in the range of about 60 μm to about 100 μm, and the third distance P_3 may be in the range of about 20 μm to about 40 μm.

As the separation distance between the plurality of bumps 200 may decrease, the thickness of the first non-conductive film 300 may increase. The thickness of the first non-conductive film 300 in the first region A_1 may be less than the thickness of the first non-conductive film 300 in the second region A_2. The thickness of the first non-conductive film 300 in the first region A_1 may be less than the thickness of the first non-conductive film 300 in the third region A_3.

In some embodiments, the first non-conductive film 300 may have a first thickness T1_300 in the first region A_1. The first non-conductive film 300 may have a second thickness T2_300 in the second region A_2. The first non-conductive film 300 may have a third thickness T3_300 in the third region A_3. The first non-conductive film 300 may have a fourth thickness T4_300 in regions not included in the first region A_1, the second region A_2, and the third region A_3.

In some embodiments, the first thickness T1_300 may be less than the second thickness T2_300. The first thickness T1_300 may be less than the third thickness T3_300. The fourth thickness T4_300 may be greater than the first thickness T1_300 and less than the second thickness T2_300.

In some embodiments, the first thickness T1_300 may be in the range of about 5 μm to about 8 μm, the second thickness T2_300 and the third thickness T3_300 may be in the range of about 9 μm to about 10 μm, and the fourth thickness T4_300 may be in the range of about 8 μm to about 9 μm.

In the semiconductor package 10a of an embodiment of the present disclosure, the thickness of the second non-conductive film 400 may be formed to be large on at least a portion of four sides of the second surface of the semiconductor chip 100. When the thickness of the second non-conductive film 400 is formed to be large, the strain rate of the non-conductive film at the same stress may be small. The separation distance between the plurality of bumps 200 at at least a portion of four sides of the second surface 101_L of the semiconductor chip 100 is large, and thus, the thickness of the second non-conductive film 400 may be formed large. During the package process, an overflow phenomenon occurring on the sides of the second surface 101_L of the semiconductor chip 100 is suppressed, and thus, the fillet phenomenon may be suppressed.

The thickness of the second non-conductive film 400 may be formed to be small at vertices and a central portion of the semiconductor chip 100. Since the separation distance between the plurality of bumps 200 at the vertices of the semiconductor chip 100 is small, the thickness of the second non-conductive film 400 may be formed smaller.

During the package process, the coverage of the non-conductive film is formed at the vertices of the semiconductor chip 100, and thus, the reliability of the semiconductor package 10a may be improved. Since the thickness of the second non-conductive film 400 is formed small at the center of the second surface 101_L of the semiconductor chip 100, the reliability of signal transmission between the semiconductor chips may be improved.

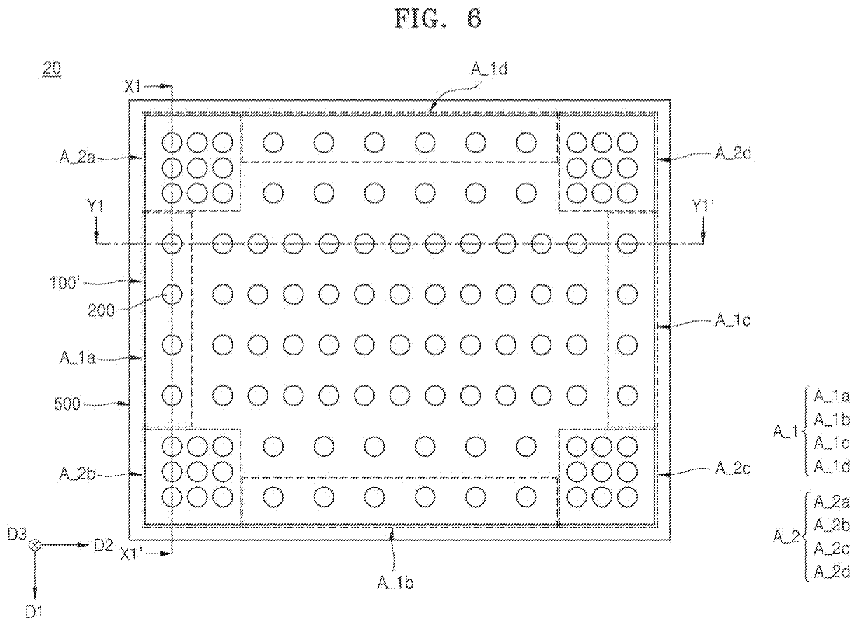

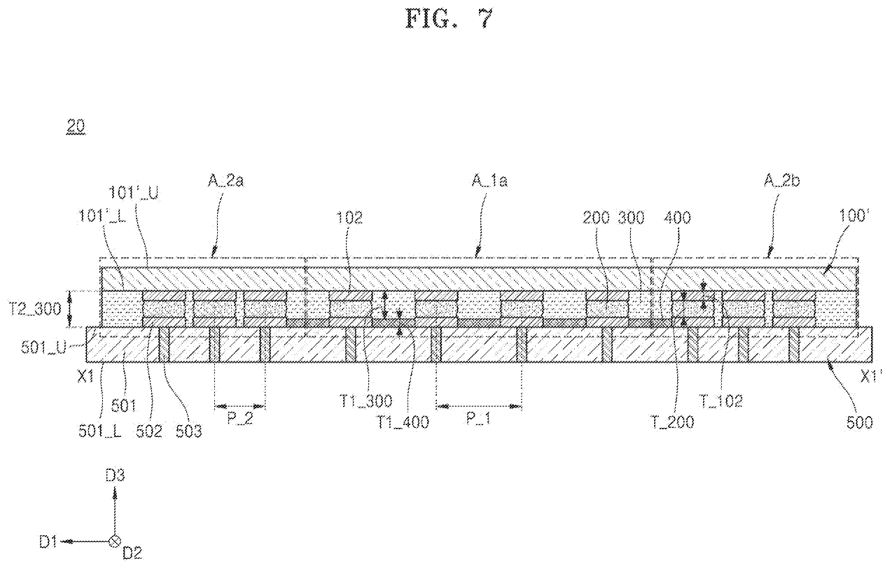

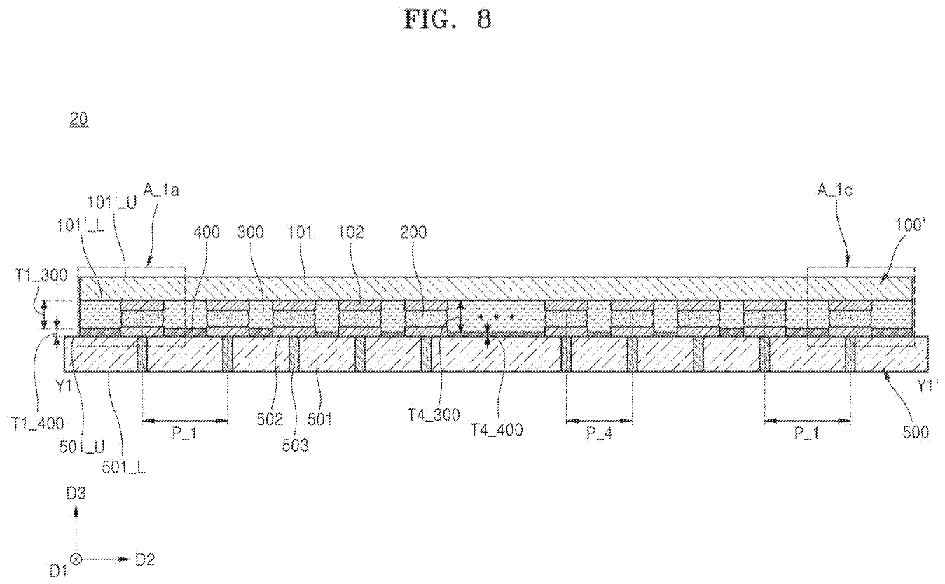

FIG. 6 is a plan view schematically illustrating a semiconductor package according to an embodiment. FIG. 7 is a cross-sectional view illustrating the semiconductor package of FIG. 6, which is taken along a line X1-X1′ in FIG. 7. FIG. 8 is a cross-sectional view illustrating the semiconductor package of FIG. 6, which is taken along a line Y-Y′ in FIG. 6.

Hereinafter, redundant description between a semiconductor package 20 of FIG. 6 and the semiconductor package 10 of FIG. 1 is omitted and a difference therebetween is described.

The semiconductor package 20 has a plurality of regions A_1 and A_2 and may include a first semiconductor chip 500, a second semiconductor chip 100′, a plurality of bumps 200, a first non-conductive film 300, and a second non-conductive film 400.

The first semiconductor chip 500 of the semiconductor package 20 may include a first substrate 501, power vias 503, and first upper pads 502.

In some embodiments, the constituent material of the first substrate 501 of the first semiconductor chip 500 may include silicon (Si). In addition, the material of the first substrate 501 may include semiconductor elements, such as germanium (Ge), or compound semiconductors, such as silicon carbide (SiC), gallium arsenide (GaAs), indium arsenide (InAs), and indium phosphate (InP).

In addition, the first substrate 501 may have a first surface 501_U and a second surface 501_L. For example, the first surface 501_U of the first substrate 501 may be one surface of the first substrate 501 on which the first upper pads 502 are arranged, and the second surface 501_L of the first substrate 501 may be one surface of the first substrate 501 on which first lower pads are arranged.

The plurality of power vias 503 of the first semiconductor chip 500 may pass through the first surface 501_U and the second surface 501_L of the first substrate 501 in a vertical direction to connect the upper pads 502 with the first lower pads. However, embodiments of the present disclosure are not limited to the above, and the power vias 503 may pass through only a portion of the first substrate 501 in a vertical direction to connect the first upper pads 502 of the first substrate 501.

The first upper pads 502 of the first semiconductor chip 500 may be arranged on the first surface 501_U of the first substrate 501 to be connected to the power vias 503. In addition, the first upper pads 502 may be pads of a conductive material. In some embodiments, the first upper pads 502 may be electrically connected to the lower pads 102 of the second semiconductor chip 100′ through a plurality of bumps.

In an embodiment, the material of the first upper pad 502 may include copper (Cu). However, embodiments of the present disclosure are not limited thereto, and the constituent materials of the first upper pads 502 may include a metal, such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), etc., or an alloy thereof.

The second semiconductor chip 100′ of the semiconductor package 20 may be positioned above the first semiconductor chip 500. The second semiconductor chip 100′ may include a substrate 101 and lower pads 102. In some embodiments, the second semiconductor chip 100′ may include the semiconductor chip 100 of FIG. 1.

A plurality of bumps 200 of the semiconductor package 20 may be positioned between the first semiconductor chip 500 and the second semiconductor chip 100′. The plurality of bumps 200 may connect the upper pads 502 with the lower pads 102. In some embodiments, the plurality of bumps 200 may include the plurality of bumps 200 of FIG. 1.

The first non-conductive film 300 of the semiconductor package 20 may be positioned on the fourth surface 101′_L of the second semiconductor chip 100′, the fourth surface 101′_L being opposite of a third surface 101′U of the second semiconductor chip 100′. The second non-conductive film 400 of the semiconductor package 20 may be positioned between the first non-conductive film 300 and the first semiconductor chip 500. In other words, the first semiconductor chip 500, the second non-conductive film 400, the first non-conductive film 300, and the second semiconductor chip 100′ may be sequentially stacked. That is, the second semiconductor chip 100′ may be spaced apart from the first semiconductor chip 500 with the first non-conductive film 300 and the second non-conductive film 400 therebetween.

The first non-conductive film 300 and the second non-conductive film 400 may have different elastic modulus. In some embodiments, the first non-conductive film 300 may have a lower elastic modulus than the second non-conductive film 400. In some embodiments, the first non-conductive film 300 and the second non-conductive film 400 may include the first non-conductive film 300 of FIG. 1 and the second non-conductive film 400 of FIG. 1.

The semiconductor package 20 may include a plurality of regions having different separation distances between the plurality of bumps 200. That is, the separation distances between the plurality of bumps 200 may vary depending on the regions of the semiconductor package 10. As the separation distance between the plurality of bumps 200 may increase, the thickness of the first non-conductive film 300 may decrease. That is, the thickness of the first non-conductive film 300 may be adjusted by adjusting the separation distance between the plurality of bumps 200.

In an embodiment, the first surface 501_U of the first semiconductor chip 500 and the fourth surface 101′_L of the second semiconductor chip 100′ may be divided into a first region A_1 and a second region A_2. In some embodiments, the first region A_1 may include at least a portion of four sides of the fourth surface 101′_L of the second semiconductor chip 100′. The second region A_2 may include four vertices of the fourth surface 101′_L of the second semiconductor chip 100′. In some embodiments, the first region A_1 and the second region A_2 may include the first region A_1 of FIG. 1 and the second region A_2 of FIG. 1, respectively.

In some embodiments, as the separation distance between the plurality of bumps 200 may decrease, the thickness of the first non-conductive film 300 may increase. The thickness of the first non-conductive film 300 in the first region A_1 may be less than the thickness of the first non-conductive film 300 in the second region A_2. In some embodiments, the thickness of the first non-conductive film 300 may be a first thickness T1_300 in the first region A_1, a second thickness T2_300 in the second region A_2, and a fourth thickness T4_300 in regions not included in the first region A_1 and the second region A_2. The first thickness T1_300 may be less than the second thickness T2_300, and the fourth thickness T4_300 may be greater than the first thickness T1_300 and less than the second thickness T2_300. In some embodiments, the first thickness T1_300, the second thickness T2_300, and the fourth thickness T4_300 may include the first thickness T1_300, the second thickness T2_300, and the fourth thickness T4_300, respectively, that were discussed above with respect to FIGS. 1-5.

Since the separation distance between the plurality of bumps 200 in the first region A_1 of the semiconductor package 20 is greater than the separation distances between the plurality of bumps 200 in other regions, the thickness of the first non-conductive film 300 may be formed smalls. When the thickness of the first non-conductive film 300 is small, the thickness of the second non-conductive film 400 may increase, and the deformation rate of the non-conductive film in the first region A_1 may decrease. By adjusting the separation distance between the plurality of bumps 200, overflow of the non-conductive film occurring at the edges of the second semiconductor chip 100′ may be suppressed, thereby suppressing the fillet phenomenon of the semiconductor package 20.

In addition, since the separation distance between the plurality of bumps 200 in the second region A_2 of the semiconductor package 20 is less than the separation distances between the plurality of bumps 200 in other regions, the thickness of the first non-conductive film 300 may be formed large. When the thickness of the first non-conductive film 300 is large, the thickness of the second non-conductive film 400 becomes small, so that the adhesion of the non-conductive film in the second region A_2 may be enhanced. It is possible to improve the quality of the semiconductor package 20 by improving coverage at the vertices of the second semiconductor chip 100′ by adjusting the separation distances between the plurality of bumps 200.

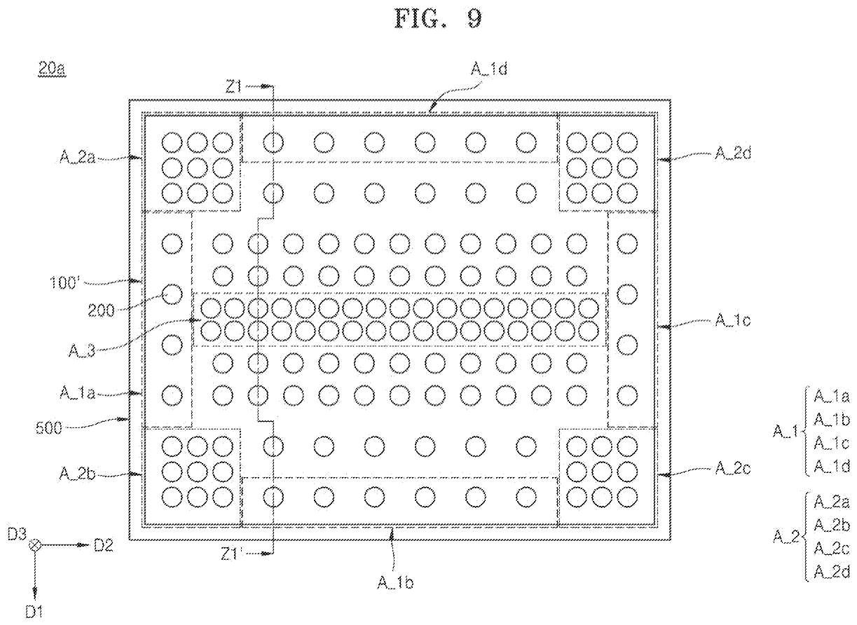

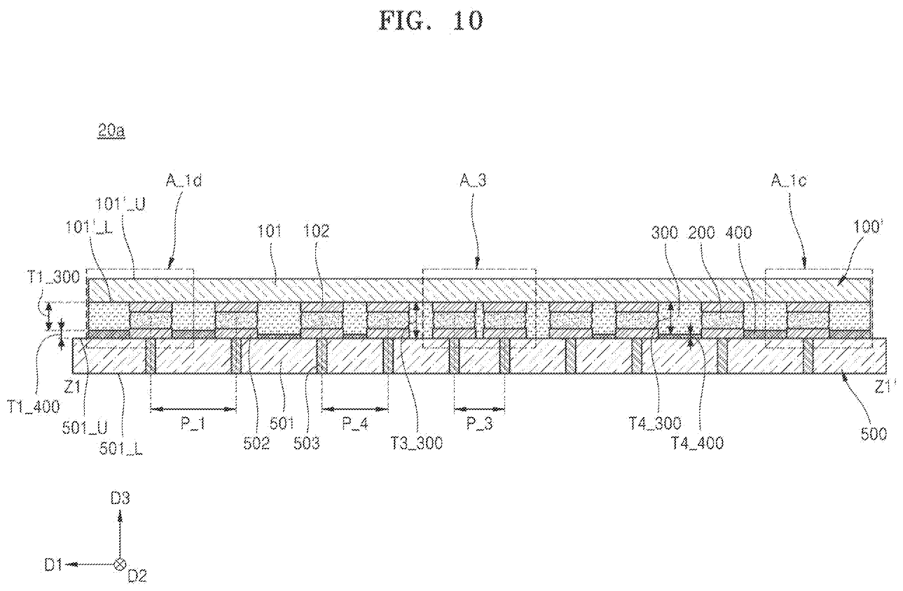

FIG. 9 is a plan view schematically illustrating a semiconductor package according to an embodiment of the present disclosure. FIG. 10 is a cross-sectional view illustrating the semiconductor package of FIG. 9, which is taken along a line Z1-Z1′ of FIG. 9.

Hereinafter, redundant description between a semiconductor package 20a of FIG. 9 and the semiconductor package 20 of FIG. 1 is omitted and a difference therebetween is described.

The semiconductor package 20a may further include a third region A_3. In some embodiments, the third region A_3 may include a central portion of the fourth surface 101′_L of the second semiconductor chip 100′. In an embodiment, the third region A_3 may be located between the first-a region A_1a and the first-c region A_1c and between the first-b region Alb and the first-d region A_1d. In some embodiments, the third region A_3 may include the third region A_3 of FIG. 4.

The separation distances between the plurality of bumps 200 of the semiconductor package 20a may be different in the first region A_1, the second region A_2, and the third region A_3. In some embodiments, the separation distance between the plurality of bumps 200 may be the first distance P_1 in the first region A_1, the second distance P_2 in the second region A_2, and the third distance P_3 in the third region A_3. In some embodiments, the first distance P_1, the second distance P_2, and the third distance P_3 may include the first distance P_1, the second distance P_2, and the third distance P_3, respectively, that were discussed above with respect to FIGS. 1-5.

As the separation distance between the plurality of bumps 200 may decrease, the thickness of the first non-conductive film 300 may increase. In some embodiments, the first non-conductive film 300 may have a first thickness T1_300 in the first region A_1. The first non-conductive film 300 may have a second thickness T2_300 in the second region A_2. The first non-conductive film 300 may have a third thickness T3_300 in the third region A_3. In some embodiments, the first thickness T1_300, the second thickness T2_300, and the third thickness T3_300 may include the first thickness T1_300, the second thickness T2_300, and the third thickness T3_300, respectively, that were discussed above with respect to FIGS. 1-5.

In the semiconductor package 20a of an embodiment of the present disclosure, the thickness of the second non-conductive film 400 may be formed to be large on at least a portion of four sides of the fourth surface 101′_L of the second semiconductor chip 100′. When the thickness of the second non-conductive film 400 is formed to be large, the strain rate of the non-conductive film at the same stress may be small. The separation distance between the plurality of bumps 200 at at least a portion of each of four sides of the fourth surface 101′_L of the second semiconductor chip 100′ is large, and thus, the thickness of the second non-conductive film 400 may be formed large. In a process of bonding the first semiconductor chip 500 to the second semiconductor chip 100′, an overflow phenomenon may be suppressed at edges of the second semiconductor chip 100′, thereby suppressing a fillet phenomenon.

The thickness of the second non-conductive film 400 may be formed to be small at vertices and a central portion of the second semiconductor chip 100′. When the thickness of the second non-conductive film 400 is formed small, wettability may increase during a bonding process between the first semiconductor chip 500 and the second semiconductor chip 100′. Since the separation distance between the plurality of bumps 200 at the vertices of the second semiconductor chip 100′ is small, the thickness of the second non-conductive film 400 may be formed small.

In a process of bonding the first semiconductor chip 500 to the second semiconductor chip 100′, the coverage of the non-conductive film is formed at the vertices of the second semiconductor chip 100′, thereby improving the reliability of the semiconductor package 20a. Since the thickness of the second non-conductive film 400 is formed small at the center of the fourth surface 101′_L of the second semiconductor chip 100′, signal transmission between the first semiconductor chip 500 and the second semiconductor chip 100′ may be facilitated.

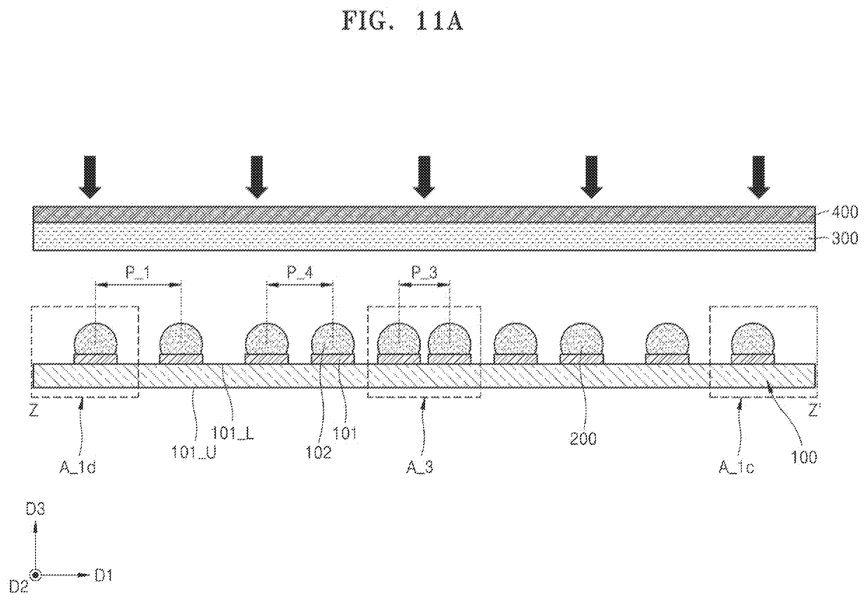

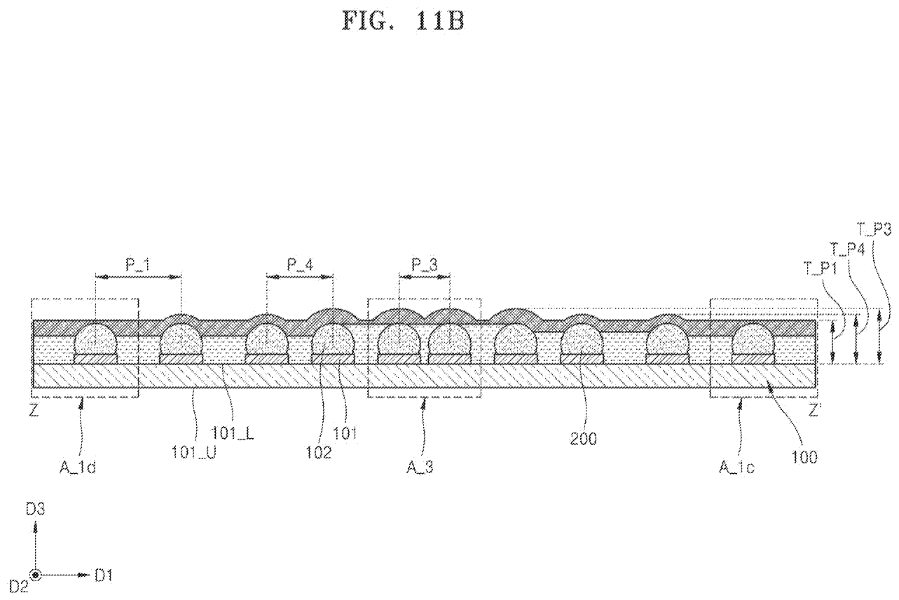

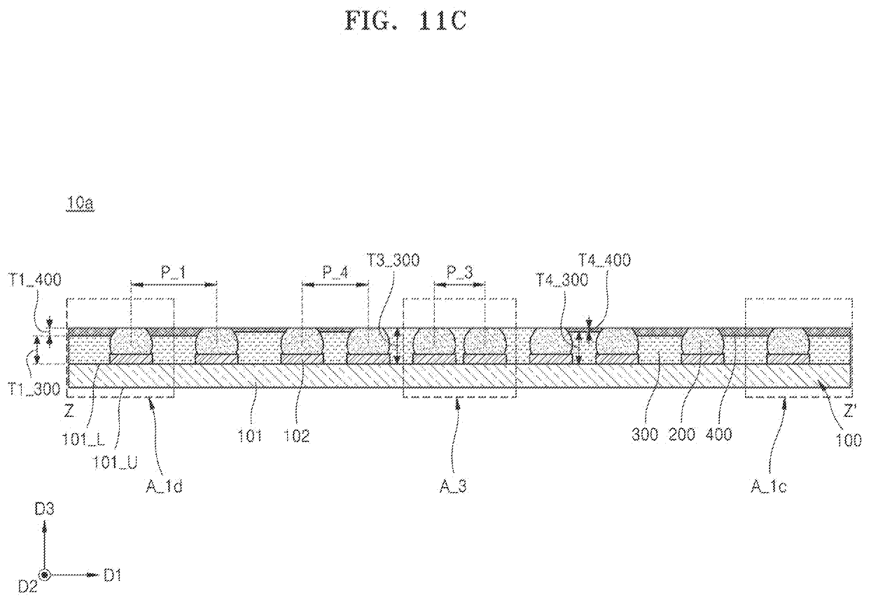

FIGS. 11A to 11C are cross-sectional views illustrating a method of manufacturing a semiconductor package, according to an embodiment in a process order. Specifically, FIGS. 11A to 11C are cross-sectional views taken along the line Z-Z′ of FIG. 4 showing a method of manufacturing the semiconductor package 10a in accordance with the process order. Hereinafter, redundant description of the semiconductor package 10 shown in FIGS. 4 and 11C is omitted.

Referring to FIG. 11A, a plurality of bumps 200 may be attached to lower pads 102 of a semiconductor chip 100. The plurality of bumps 200 may have different separation distances depending on regions of the semiconductor package 10a. In some embodiments, the separation distance between the plurality of bumps 200 in the first-d region A_1d may be the first distance P_1 and the separation distance between the plurality of bumps 200 in the third region A_3 may be the third distance P_3. The first distance P_1 may be greater than the third distance P_3. The first non-conductive film 300 may have a thickness of about 6 μm to about 9 μm before being attached to the semiconductor chip 100. The second non-conductive film 400 may have a thickness of about 3 μm to about 5 μm before being attached to the semiconductor chip 100.

Referring to FIG. 11B, the first non-conductive film 300 and the second non-conductive film 400 may be attached on the semiconductor chip 100. The sum of the thicknesses of the first non-conductive film 300 and the second non-conductive film 400 may vary depending on the separation distances between the plurality of bumps 200. In other words, in a region in which the separation distance between the plurality of bumps 200 is small, the thicknesses of the first non-conductive film 300 and the second non-conductive film 400 may increase after adhesion than before adhesion. In some embodiments, the semiconductor package 10a may have a first height T_P1 in the first-d region A_1d, a third height T_P3 in the third region A_3, and a fourth height T_P4 in the fourth region. The third height T_P3 may be greater than the fourth height T_P4, and the first height T_P1 may be less than the fourth height T_P4. In some embodiments, the third height T_P3 may be in the range of about 120% to about 130% of the first height T_P1. The fourth height T_P4 may be in the range of about 100% to about 120% of the first height T_P1.

Referring to FIG. 11C, the plurality of bumps 200 may be exposed to the outside by removing some portions of the first non-conductive film 300 and the second non-conductive film 400 through a planarization process. In other words, through the planarization process, the sum of the thicknesses of the first non-conductive film 300 and the second non-conductive film 400 may be the same in all regions. In addition, the sum of the thicknesses of the first non-conductive film 300 and the second non-conductive film 400 may be equal to the sum of the thicknesses of each of the lower pads 102 and each of the plurality of bumps 200. In some embodiments, during the planarization process, the third height T_P3 is greater than the first height T_P1, and thus, a portion of the second non-conductive film 400 removed in the third region A_3 may be larger than a portion of the second non-conductive film 400 removed in the first-d region A_1d. For example, a thickness of the portion the second non-conductive film 400 removed in the third region A_3 may be greater than a thickness of portion of the second non-conductive film 400 removed in the first-d region A_1d. In some embodiments, the first thickness T1_300 may be in the range of about 5 μm to about 8 μm, and the third thickness T3_300 may be in the range of about 9 μm to about 10 μm.

While non-limiting example embodiments have been particularly shown and described with reference to the drawings, it will be understood that various changes in form and details may be made therein without departing from the spirit and scope of the present disclosure.

What is claimed is:

1. A semiconductor package comprising:
a semiconductor chip comprising:
a substrate comprising a first surface and a second surface opposite to the first surface; and
a plurality of lower pads on the second surface at different intervals;
a plurality of bumps attached to the plurality of lower pads;
a first non-conductive film on the second surface of the substrate; and
a second non-conductive film on the first non-conductive film,
wherein a plurality of regions are defined in the semiconductor package according to a separation distance between the plurality of bumps, such that each region of the plurality of regions comprises respective bumps, from among the plurality of bumps, that have a respective separation distance between neighboring ones of the respective bumps within the region,
wherein a sum of thicknesses of the first non-conductive film and the second non-conductive film is constant, and
wherein an elastic modulus of the first non-conductive film and an elastic modulus of the second non-conductive film are different from each other.

2. The semiconductor package of claim 1, wherein a thickness of the first non-conductive film decreases as a distance between neighboring ones of the plurality of bumps increases.

3. The semiconductor package of claim 1, wherein the elastic modulus of the second non-conductive film is greater than the elastic modulus of the first non-conductive film.

4. The semiconductor package of claim 1, wherein the sum of thicknesses of the first non-conductive film and the second non-conductive film is the same as a sum of thicknesses of each of the plurality of lower pads and each of the plurality of bumps.

5. The semiconductor package of claim 1, wherein the sum of thicknesses of the first non-conductive film and the second non-conductive film is in a range of 7 μm to 11 μm.

6. The semiconductor package of claim 1, wherein
the first non-conductive film or the second non-conductive film is on a side surface of each of the plurality of bumps, and
the first non-conductive film or the second non-conductive film is not on upper and lower surfaces of each of the plurality of bumps.

7. The semiconductor package of claim 1, wherein
the plurality of regions comprises a first region and a second region,
the first region comprises at least a portion of each of four sides of the second surface of the semiconductor chip,
the second region comprises four vertices of the second surface of the semiconductor chip, and
the separation distance between the neighboring ones of the respective bumps of the first region is different from the separation distance between the neighboring ones of the respective bumps of the second region.

8. The semiconductor package of claim 7, wherein a portion of the first region is located between a first portion of the second region and a second portion of the second region,
wherein the portion of the first region comprises a portion of one side of the second surface of the semiconductor chip, and
wherein the first portion of the second region comprises a first vertex of the second surface of the semiconductor chip, and the second portion of the second region comprises a second vertex of the second surface of the semiconductor chip.

9. The semiconductor package of claim 7, wherein
the separation distance between the neighboring ones of the respective bumps of the first region is a first distance,
the separation distance between the neighboring ones of the respective bumps of the second region is a second distance, and
the second distance is less than the first distance.

10. The semiconductor package of claim 9, wherein
the first distance is in a range of 60 μm to 100 μm, and
the second distance is in a range of 20 μm to 40 μm.

11. The semiconductor package of claim 7, wherein a thickness of a portion of the first non-conductive film in the first region is different from a thickness of a portion of the first non-conductive film in the second region.

12. The semiconductor package of claim 11, wherein the first non-conductive film has a first thickness in the first region and has a second thickness in the second region, and the second thickness is greater than the first thickness.

13. The semiconductor package of claim 12, wherein
the first thickness is in a range of 60% to 90% of the sum of the thicknesses of the first non-conductive film and the second non-conductive film, and
the second thickness is in a range of about 90% to about 100% of the sum of the thicknesses of the first non-conductive film and the second non-conductive film.

14. The semiconductor package of claim 7, wherein
the plurality of regions further comprises a third region that comprises a central region of the second surface of the semiconductor chip,
the separation distance between the neighboring ones of the respective bumps of the first region is a first distance, and
the separation distance between the neighboring ones of the respective bumps of the third region is less than the first distance.

15. The semiconductor package of claim 14, wherein a thickness of a portion of the first non-conductive film within the third region is greater than a thickness of a portion of the first non-conductive film within the first region.

16. A semiconductor package comprising:
a first semiconductor chip comprising:
a first substrate comprising a first surface and a second surface opposite to the first surface;
a plurality of power vias penetrating at least a portion of the first substrate between the first surface and the second surface of the first substrate; and
a plurality of first upper pads on the first surface of the first substrate at different intervals;
a second semiconductor chip comprising:
a second substrate comprising a third surface and a fourth surface opposite to the third surface; and
a plurality of second lower pads, corresponding to the plurality of first upper pads, on the fourth surface of the second substrate;
a plurality of bumps between the first semiconductor chip and the second semiconductor chip and connecting the plurality of first upper pads to the plurality of second lower pads;
a first non-conductive film on the fourth surface of the second semiconductor chip; and
a second non-conductive film between the first non-conductive film and the first semiconductor chip;
wherein a plurality of regions are defined in the semiconductor package according to a separation distance between the plurality of bumps, such that each region of the plurality of regions comprises respective bumps, from among the plurality of bumps, that have a respective separation distance between neighboring ones of the respective bumps within the region, and
wherein an elastic modulus of the first non-conductive film and an elastic modulus of the second non-conductive film are different from each other.

17. The semiconductor package of claim 16, wherein the elastic modulus of the first non-conductive film is less than the elastic modulus of the second non-conductive film.

18. The semiconductor package of claim 16, wherein
the plurality of regions comprises a first region, a second region, and a third region,
the first region comprises at least a portion of each of four sides of the fourth surface of the second substrate of the second semiconductor chip,
the second region comprises four vertices of the fourth surface of the second semiconductor chip,
the third region comprises a central region of the fourth surface of the second semiconductor chip, and
the separation distance between the neighboring ones of the respective bumps of the second region and the separation distance between the neighboring ones of the respective bumps of the third region are less than the separation distance between the neighboring ones of the respective bumps of the first region.

19. The semiconductor package of claim 18, wherein
the first non-conductive film and the second non-conductive film fill a space between the first semiconductor chip and the second semiconductor chip, and
a thickness of a portion of the first non-conductive film in the first region is less than thicknesses of portions of the first non-conductive film in the second region and in the third region.

20. A semiconductor package comprising:
a semiconductor chip comprising:
a substrate comprising a first surface and a second surface opposite to the first surface; and
a plurality of lower pads on the second surface;
a plurality of bumps attached to the plurality of lower pads;
a first non-conductive film on the second surface; and
a second non-conductive film on the first non-conductive film,
wherein an elastic modulus of the second non-conductive film is greater than an elastic modulus of the first non-conductive film,
wherein a plurality of regions are defined in the semiconductor package according to a separation distance between the plurality of bumps, such that each region of the plurality of regions comprises respective bumps, from among the plurality of bumps, that have a respective separation distance between neighboring ones of the respective bumps within the region,
wherein the plurality of regions comprises:
a first region that comprises at least a part of each of four sides of the second surface of the semiconductor chip;
a second region that comprises four vertices of the second surface of the semiconductor chip; and
a third region that comprises a central region of the second surface of the semiconductor chip,
wherein a sum of thicknesses of the first non-conductive film and the second non-conductive film is the same as a sum of thicknesses of the plurality of bumps and the plurality of lower pads,
wherein the separation distance between the neighboring ones of the respective bumps of the first region is greater than the separation distance between the neighboring ones of the respective bumps of the second region and the separation distance between the neighboring ones of the respective bumps of the third region, and
wherein a thickness of a portion of the first non-conductive film in the first region is less than thicknesses of portions of the first non-conductive film in the second region and the third region.
